(19) United States
(12) Patent Application Publication
(10) Pub. No.: US 2014/0268520 A1
(43) Pub. Date: Sep. 18, 2014

(54) METHOD OF MANUFACTURING MEMBER WITH SEALING MATERIAL LAYER, MEMBER WITH SEALING MATERIAL LAYER, AND MANUFACTURING APPARATUS

(71) Applicant: ASAHI GLASS COMPANY, LIMITED, Chiyoda-ku (JP)

(72) Inventors: Ryota MURAKAMI, Chiyoda-ku (JP); Satoshi TAKEDA, Chiyoda-ku (JP); Yohei NAGAO, Chiyoda-ku (JP)

(73) Assignee: ASAHI GLASS COMPANY, LIMITED, Chiyoda-ku (JP)

(21) Appl. No.: 14/206,060

(22) Filed: Mar. 12, 2014

(30) Foreign Application Priority Data
Mar. 13, 2013 (JP) 2013-050798

(51) Int. Cl. B29D 11/00; H05K 5/06

(52) U.S. Cl. CPC B29D 11/0073; H05K 5/06
USPC 361/679.01; 427/554; 118/620

(57) ABSTRACT

A method of manufacturing a member with a sealing material layer has a substrate preparation step, a coating step, a firing step, and a pre-process step. In the substrate preparation step, a substrate having a frame-shaped sealing region is prepared. In the coating step, a sealing material paste is applied on the sealing region of the substrate to form a frame-shaped coating layer. In the firing step, irradiation is performed while firing laser light is scanned along the frame-shaped coating layer, to form a sealing material layer. The pre-process step is performed before the irradiation of the firing step is started. In the pre-process step, irradiation is performed at an irradiation start position for a time within 0.2 D/V to 0.5 D/V [s], where D [mm] and V [mm/s] are a beam diameter and a scanning speed of the firing laser light in the firing step respectively.

### CROSS-REFERENCE TO RELATED APPLICATIONS

This application is based upon and claims the benefit of priority from the prior Japanese Patent Application No. 2013-050798, filed on Mar. 13, 2013; the entire contents of all of which are incorporated herein by reference.

### FIELD

The present invention relates to a method of manufacturing a member with a sealing material layer, a member with a sealing material layer, and a manufacturing apparatus.

### BACKGROUND

A flat panel display (FPD) such as an organic EL display (Organic Electro-Luminescence Display: OELD) and a plasma display panel (PDP) has a structure in which light-emitting elements are sealed by a glass package in which a pair of glass substrates is sealingly bonded. A liquid crystal display (LCD) also has a structure in which liquid crystals are sealed between a pair of glass substrates. Further, a solar cell such as an organic thin-film solar cell and a dye-sensitized solar cell also has a structure in which solar cell elements (photoelectric conversion elements) are sealed between a pair of glass substrates.

Sealing glass is suitably used for sealing. In the sealing by the sealing glass, for example, a sealing material layer containing the sealing glass is disposed in a frame shape between a pair of glass substrates to form a glass assembly, and this sealing material layer is heated to 400° C. to 600° C. At this time, when the whole glass assembly is heated by using a firing furnace, light emitting elements and so on are likely to be damaged by the heating. Therefore, the application of laser sealing that heats only the sealing material layer by using laser light (sealing laser light) has been considered.

Concretely, the laser sealing is done as follows. First, the sealing glass is mixed with a vehicle to prepare a sealing material paste. This sealing material paste is applied on a frame-shaped sealing region of one of the glass substrates on which the light emitting elements and so on are not mounted, to form a frame-shaped coating layer, and the frame-shaped coating layer is heated to a firing temperature of the sealing glass (temperature equal to or higher than a softening temperature of the sealing glass). Consequently, the sealing glass is melted and is baked to the glass substrate, so that the sealing material layer is formed. Next, the glass substrate having the sealing material layer and the other glass substrate on which the light emitting elements and so on are mounted are stacked via the sealing material layer. Thereafter, the sealing laser light is radiated to the sealing material layer via the glass substrate to heat and melt the sealing material layer. Consequently, the pair of glass substrates is joined by a sealing layer made of the sealing glass.

Conventionally, the formation of the sealing material layer, that is, the firing of the frame-shaped coating layer is done by heating the whole glass substrate including the frame-shaped coating layer by using a heating furnace. However, in a FPD package, organic resin films such as color filters are formed also on the glass substrate on which the light emitting elements and so on are not mounted. Therefore, heating the whole glass substrate causes damage to the organic resin films. Similarly, in the dye-sensitized solar cell as well, since element films and so on are formed on the glass substrate on which the sealing material layer is formed, heating the whole glass substrate causes damage to the element films and so on. Further, when the heating furnace is used, it takes a long time to form the sealing material layer and an energy consumption amount becomes large.

From such a point of view, to use laser light (firing laser light) for the formation of the sealing material layer has been considered. When the firing laser light is used, only the sealing material layer is heated, which suppresses damage to the organic resin films and so on and reduces an energy consumption amount. Incidentally, when the firing laser light is radiated while scanning round the sealing material layer once, a portion where the sealing material layer is discontinuous (gap) sometimes occurs at an irradiation start position or an irradiation finish position. The gap, if excessively large, deteriorates airtightness, adhesive strength, and so on at the time when the pair of glass substrates is sealingly joined.

As a method to reduce the size of the gap, there have been known a method to increase power density of the firing laser light near the irradiation start position and the irradiation finish position, and a method to use a pair of firing laser lights and make the pair of firing laser lights overlap with each other at the irradiation start position and the irradiation finish position. There has also been known a method to lower a scanning speed of the firing laser light near the irradiation finish position.

Increasing the power density in a partial region is likely to generate regions having different firing states unless power control is appropriately performed. The use of the pair of firing laser lights requires a plurality of laser irradiation heads, power control parts, and so on. Further, in the above case, regions having different firing states are generated unless power control is performed appropriately, which is likely to deteriorate airtightness, adhesive strength, and so on.

Reducing the scanning speed halfway is likely to generate regions having different firing states unless power control is appropriately performed. Further, though in a widthwise center portion of the sealing material layer, the gap becomes small due to re-melting, the gap does not necessarily become small at widthwise both end portions. In this case, since the width of the sealing material layer becomes narrow, airtightness, adhesive strength, and so on are not necessarily good. Further, reducing the scanning speed halfway is likely to increase the firing time.

### SUMMARY

A method of manufacturing a member with a sealing material layer of an embodiment has a substrate preparation step, a coating step, a firing step, and a pre-process step. In the substrate preparation step, a substrate having a frame-shaped sealing region is prepared. In the coating step, a sealing material paste prepared by mixing a sealing material containing sealing glass and a laser absorbing material with a vehicle containing an organic binder is applied on the sealing region of the substrate to form a frame-shaped coating layer. In the firing step, irradiation is performed while firing laser light is scanned along the frame-shaped coating layer, to heat the whole frame-shaped coating layer. This firing step fires the sealing material to form a sealing material layer while removing the organic binder in the frame-shaped coating layer. The pre-process step is performed before the irradiation of the firing step is started. In the pre-process step, irradiation is performed at an irradiation start position for a time within 0.2 D/V to 0.5 D/V [s], where D [mm] and V [mm/s] are a beam diameter and a scanning speed of the firing laser light in the firing step respectively.

A member with a sealing material layer of an embodiment has a substrate having a frame-shaped sealing region and a sealing material layer provided on the sealing region of the substrate, and is manufactured by the method of manufacturing the member with the sealing material layer of the embodiment.

A method of manufacturing an electronic device of an embodiment has a substrate preparation step, a coating step, a firing step, a stacking step, a sealing step, and a pre-process step. In the substrate preparation step, a first substrate having a first surface on which a frame-shaped first sealing region is provided and a second substrate having a second surface on which a second sealing region corresponding to the first sealing region is provided are prepared. In the coating step, a sealing material paste prepared by mixing a sealing material containing sealing glass and a laser absorbing material with a vehicle containing an organic binder is applied on the second sealing region of the second substrate to form a frame-shaped coating layer. In the firing step, irradiation is performed while firing laser light is scanned along the frame-shaped coating layer, to heat the whole frame-shaped coating layer. The firing step fires the sealing material to form a sealing material layer while removing the organic binder in the frame-shaped coating layer. In the stacking step, the first substrate and the second substrate are stacked via the sealing material layer, with the first surface and the second surface facing each other. In the sealing step, the sealing material layer is irradiated with sealing laser light via the first substrate or the second substrate, whereby the sealing material layer is melted and a sealing layer which seals an electronic element part provided between the first substrate and the second substrate is formed. The pre-process step is performed before the irradiation of the firing step is started. In the pre-process step, irradiation is performed at an irradiation start position for a time within 0.2 D/V to 0.5 D/V [s], where D [mm] and V [mm/s] are a beam diameter and a scanning speed of the firing laser light in the firing step respectively.

An electronic device of an embodiment has a first substrate, a second substrate, and a sealing layer. The first substrate has a first surface on which a frame-shaped first sealing region is provided. The second substrate has a second surface on which a second sealing region corresponding to the first sealing region is provided and is disposed, with the first surface and the second surface facing each other. The sealing layer is disposed in a frame shape so as to seal an electronic element part between the first substrate and the second substrate. The electronic device of the embodiment is manufactured by the method of manufacturing the electronic device of the embodiment.

A manufacturing apparatus of an embodiment has a sample stage, a laser light source, a laser irradiation head, a power control part, a moving mechanism, and a scanning control part. On the sample stage, a substrate is placed, the substrate having a frame-shaped coating layer of a sealing material paste prepared by mixing a sealing material containing sealing glass and a laser absorbing material with a vehicle containing an organic binder. The laser light source emits firing laser light. The laser irradiation head has an optical system which irradiates the frame-shaped coating layer of the substrate with the laser light emitted from the laser light source. The power control part controls power of the firing laser light with which the frame-shaped coating layer is irradiated by the laser irradiation head. The moving mechanism relatively moves positions of the sample stage and the laser irradiation head. The scanning control part controls the moving mechanism so that irradiation is performed while the firing laser light is scanned along the frame-shaped coating layer. Further, the scanning control part controls the moving mechanism so that irradiation is performed at an irradiation start position of the firing laser light for a time within 0.2 D/V to 0.5 D/V [s], where D [mm] is a beam diameter of the firing laser light and V [mm/s] is a scanning speed of the firing laser light.

### BRIEF DESCRIPTION OF THE DRAWINGS

FIG. 1A to FIG. 1D are cross-sectional views illustrating manufacturing steps of an electronic device.

FIG. 2 is a plane view illustrating a first substrate having an electronic element part.

FIG. 3 is a cross-sectional view illustrating the first substrate taken along A-A line in FIG. 2.

FIG. 4 is a plane view illustrating a second substrate having a sealing material layer.

FIG. 5 is a cross-sectional view illustrating the second substrate taken along B-B line in FIG. 4.

FIG. 6A to FIG. 6C are cross-sectional views illustrating steps of forming the sealing material layer.

FIG. 7 is a view illustrating a scanning example of firing laser light.

FIG. 8 is a plane view illustrating an example of the sealing material layer.

FIG. 9A to FIG. 9D are views illustrating positional relations between an irradiation start position and an irradiation finish position of the firing laser light.

FIG. 10A to FIG. 10B are views illustrating a start position of a second firing step.

FIG. 11A to FIG. 11D are explanatory views of a scanning speed in the second firing step.

FIG. 12 is a plane view illustrating one embodiment of a manufacturing apparatus.

FIG. 13 is a front view of the manufacturing apparatus illustrated in FIG. 12.

FIG. 14 is a view illustrating one embodiment of a laser irradiation head.

### DETAILED DESCRIPTION

Hereinafter, modes for carrying out the present invention will be described with reference to the drawings. FIG. 1A to FIG. 6C are views illustrating one embodiment of manufacturing steps of an electronic device.

Examples of the electronic device are FPD, a lighting device, a solar cell, and the like. Examples of FPD are OELD, FED, PDP, LCD, and the like. Examples of the lighting device are those using a light-emitting element such as an OEL element. Examples of the solar cell are sealed-type solar cells such as a dye-sensitized solar cell, a thin-film silicon solar cell, and a compound semiconductor-based solar cell.

First, as illustrated in FIG. 1A, a first substrate 1 and a second substrate 2 are prepared (substrate preparation step). As the first and second substrates 1, 2, glass substrates made of alkali free soda lime glass, or the like having a well-known composition is used, for instance. Alternatively, as the first and second substrates 1, 2, glass ceramics substrates made of glass ceramics in which a ceramics powder is dispersed in glass are used as required.

The alkali free glass has a coefficient of thermal expansion of about 30 to 50×10⁻⁷/K. The soda lime glass has a coefficient of thermal expansion of about 80 to 90×10⁻⁷/K. A typical glass composition of the alkali free glass is a composition containing, by mass %, 50% to 70% SiO₂, 1% to 20% Al₂O₃, 0% to 15% B₂O₃, 0% to 30% MgO, 0% to 30% CaO, 0% to 30% SrO, and 0% to 30% BaO. A typical glass composition of the soda lime glass is a composition containing, by mass %, 55% to 75% SiO₂, 0.5% to 10% Al₂O₃, 2% to 10% CaO, 0% to 10% SrO, 1% to 10% Na₂O, and 0% to 10% K₂O. Note that the glass composition is not limited to these. Further, at least one of the first and second substrates 1, 2 may be chemically tempered glass or the like.

As illustrated in FIG. 2 and FIG. 3, the first substrate 1 has a surface 1a on which an element region 3 is provided. On the element region 3, an electronic element part 4 according to an electronic device being a target is provided. The electronic element part 4 includes, for example, an OEL element if the electronic device is OELD or OEL lighting, an electron emitting element if it is FED, a plasma light-emitting element if it is PDP, a liquid crystal display element if it is LCD, and a solar cell element if it is a solar cell. The electronic element part 4 including a light emitting element such as the plasma light-emitting element or the OEL element, a display element such as the liquid crystal display element, the solar cell element such as a dye-sensitized solar cell element, or the like has various kinds of well-known structures. The element structure of the electronic element part 4 is not particularly limited. On a peripheral portion of the surface la of the first substrate 1, a first sealing region 5 in a frame shape is provided along an outer periphery of the element region 3.

As illustrated in FIG. 4 and FIG. 5, the second substrate 2 has a surface 2a facing the surface 1a of the first substrate 1. On a peripheral portion of the surface 2a, a second sealing region 6 in a frame shape corresponding to the first sealing region 5 is provided. The first and second sealing regions 5, 6 become formation regions of a sealing layer. The second sealing region 6 also becomes a formation region of a sealing material layer.

The electronic element part 4 is provided between the surface 1a of the first substrate 1 and the surface 2a of the second substrate 2. In the manufacturing steps of the electronic device illustrated in FIG. 1A to FIG. 1D, the first substrate 1 corresponds to an element glass substrate on whose surface 1a the element structure such as the OEL element or the PDP element is provided as the electronic element part 4. The second substrate 2 corresponds to a sealing glass substrate which seals the electronic element part 4 formed on the surface 1a of the first substrate 1. However, the structure of the electronic element part 4 is not limited to this.

For example, when the electronic element part 4 is the dye-sensitized solar cell element or the like, element films such as wiring films and electrode films which form the element structure are formed on each of the surfaces 1a, 2a of the first and second substrates 1, 2. The element films forming the electronic element part 4 and the element structure based on these are formed on at least one of the surfaces 1a, 2a of the first and second substrates 1, 2. Further, on the surface 2a of the second substrate 2 forming the sealing glass substrate, organic resin films such as color filters are sometimes formed as previously described.

On the sealing region 6 of the second substrate 2, the sealing material layer 7 is formed along the whole periphery or substantially the whole periphery of the peripheral portion of the second substrate 2, as illustrated in FIG. 1A, FIG. 4, and FIG. 5. The sealing material layer 7 is a fired layer of a sealing material containing sealing glass and a laser absorbing material. The sealing material can contain an inorganic filler such as a low-expansion filler when necessary, and can further contain other fillers and additives.

As the sealing glass, low-melting-point glass such as tin-phosphoric acid-based glass, bismuth-based glass, vanadium-based glass, or lead-based glass is used, for instance. Among them, low-melting-point sealing glass made of tin-phosphoric acid-based glass or bismuth-based glass is preferable in consideration of sealability (adhesiveness) to the first and second substrates 1, 2 and reliability thereof (adhesion reliability and hermetically) and further an influence on environments and human bodies.

The tin-phosphoric acid-based glass preferably has a composition containing 55 mole % to 68 mole % SnO, 0.5 mole % to 5 mole % SnO₂, and 20 mole % to 40 mole % P₂O₅ (basically, the total amount is 100 mole %).

The bismuth-based glass preferably has a composition containing 70 mass % to 90 mass % Bi₂O₃, 1 mass % to 20 mass % ZnO, and 2 mass % to 12 mass % B₂O₃ (basically, the total amount is 100 mass %).

The sealing material contains the laser absorbing material. As the laser absorbing material, at least one kind of metal selected from Fe, Cr, Mn, Co, Ni, and Cu and/or at least one kind of a metal compound of an oxide or the like containing the aforesaid metal are (is) used, for instance. Further, other pigment, for example, an oxide of vanadium (concretely, VO, VO₂, and V₂O₅) may be used.

The content of the laser absorbing material is preferably within a range of 0.1 vol % to 40 vol % to the sealing material. When the content of the laser absorbing material is less than 0.1 vol %, it may not be possible to melt the sealing material layer 7 sufficiently. When the content of the laser absorbing material is over 40 vol %, heat is liable to be generated locally near an interface with the second substrate 2. Further, when the content of the laser absorbing material is over 40 vol %, flowability of the sealing material is liable to deteriorate at the time of its melting to lower adhesiveness with the first substrate 1. The content of the laser absorbing material is preferably 37 vol % or less.

The sealing glass or glass frit, the laser absorbing material, and the low-expansion filler are each in a powdery form or in a particulate form. Hereinafter, the sealing glass powder will be sometimes simply referred to as sealing glass or glass frit, the laser absorbing material particles or the laser absorbing material powder will be sometimes simply referred to as a laser absorbing material, and the low-expansion filler particles or the low-expansion filler powder will be sometimes simply referred to as a low-expansion filler.

The sealing material contains the low-expansion filler lower in a coefficient of thermal expansion than the sealing glass as required. The low-expansion filler is preferably at least one kind selected from silica, alumina, zirconia, zirconium silicate, aluminum titanate, mullite, cordierite, eucryptite, spodumene, a zirconium phosphate-based compound, a quartz solid solution, soda lime glass, and borosilicate glass. Examples of the zirconium phosphate-based compound are (ZrO)₂P₂O₇, NaZr₂(PO₄)₃, KZr₂(PO₄)₃, Ca_{0.5}Zr₂(PO₄)₃, NbZr(PO₄)₃, Zr₂(WO₃)(PO₄)₂, and a complex compound of these.

The content of the low-expansion filler is preferably set so that the coefficient of thermal expansion of the sealing glass becomes close to a coefficient of thermal expansion of the first and second substrates 1, 2. Concretely, though depending on the coefficients of thermal expansion of the sealing glass and the first and second substrates 1, 2, the content is preferably within a range of 0.1 vol % to 50 vol % to the sealing material. The content can be appropriately changed depending on a thickness or the like of the sealing material layer 7. However, when the content is over 50 vol %, flowability of the sealing material at the time of its melting is liable to deteriorate to lower adhesiveness with the first substrate 1. The content is preferably 45 vol % or less. Since the total content of itself and the laser absorbing material influences a property of the sealing material, the total content of these is preferably within a range of 0.1 vol % to 50 vol %.

Hereinafter, a method of forming the sealing material layer 7 (a method of manufacturing a member with a sealing material layer) will be described. First, the laser absorbing material, the low-expansion filler, and so on are compounded to the sealing glass to fabricate the sealing material, and the sealing material is mixed with a vehicle to prepare a sealing material paste.

The vehicle is prepared by melting an organic binder in a solvent. As the organic binder, used is, for example: cellulose-based resin such as methyl cellulose, ethyl cellulose, carboxymethyl cellulose, oxyethyl cellulose, benzyl cellulose, propyl cellulose, or nitrocellulose; organic resin such as acrylic resin obtained by polymerizing one kind or more of acrylic monomers such as methyl methacrylate, ethyl methacrylate, butyl methacrylate, 2-hydroxyethyl methacrylate, butyl acrylate, and 2-hydroxyethyl acrylate; or aliphatic polyolefin-based carbonate resin such as polyethylene carbonate or polypropylene carbonate. As the solvent, in the case of the cellulose-based resin, a solvent such as terpineol, butyl carbitol acetate, or ethylcarbitol acetate is used, in the case of the acrylic resin, a solvent such as methyl ethyl ketone, terpineol, butyl carbitol acetate, or ethyl carbitol acetate is used, and in the case of the aliphatic polyolefin-based carbonate, propylene carbonate, triacetin, or acetyl triethyl citrate is used.

The viscosity of the sealing material paste preferably conforms to the viscosity adapted to an apparatus which applies the sealing material paste on the second substrate 2. The viscosity of the sealing material paste can be adjusted by a ratio of the organic binder and the solvent or a ratio of the sealing material and the vehicle. Well-known additives in a glass paste such as a defoaming agent and a dispersing agent may be added to the sealing material paste. A well-known method using a mixer of a rotation type including stirring blades, a roll mill, a ball mill, or the like is applicable to the preparation of the sealing material paste.

Thereafter, as illustrated in FIG. 6A, the sealing material paste is applied along the whole periphery or along substantially the whole periphery of the frame-shaped sealing region 6 provided on the peripheral portion of the second substrate 2 and is dried, whereby a frame-shaped coating layer 8 is formed (coating step). To apply the sealing material paste, a printing method such as screen printing or gravure printing is employed, or a dispenser or the like is used, for instance. The frame-shaped coating layer 8 is preferably dried at a temperature equal to or higher than 120° C. for ten minutes or longer, for instance. The drying is intended to remove the solvent in the frame-shaped coating layer 8. If the solvent remains in the frame-shaped coating layer 8, it may not be possible to remove the organic binder sufficiently in a later firing step.

Further, as illustrated in FIG. 6B, irradiation is performed while firing laser light 9 is scanned along the frame-shaped coating layer 8 (firing step). Consequently, the sealing material is fired while the organic binder in the frame-shaped layer 8 is removed, so that the sealing material layer 7 is formed (FIG. 6C). The firing laser light 9 is not particularly limited, but desired laser light out of diode laser, carbon dioxide laser, excimer laser, YAG laser, He—Ne laser, and the like is used. The same applies to later-described sealing laser light.

A thickness of the frame-shaped coating layer 8 is preferably set so that a thickness after the firing becomes 1 μm or more, that is, so that a thickness of the sealing material layer 7 becomes 1 μm or more. In such a case, by adjusting a formation condition of the frame-shaped coating layer 8, an irradiation condition of the firing laser light 9, or the like, it is possible to fire the frame-shaped coating layer 8 well. The thickness of the frame-shaped coating layer 8 is more preferably set so that the thickness after the firing becomes 150 μm or less. In view of uniform firing, the thickness of the frame-shaped coating layer 8 is still more preferably set so that the thickness after the firing becomes 20 μm or less. A width of the frame-shaped coating layer 8 is preferably set so that a width after the firing becomes 0.1 mm to 5.0 mm, more preferably 0.2 mm to 3.0 mm, and still more preferably 0.5 mm to 2.0 mm.

In the firing, as illustrated in FIG. 7, the irradiation is performed while the firing laser light 9 is scanned from an irradiation start position S of the frame-shaped coating layer 8 up to an irradiation finish position F which at least partly overlaps with the irradiation start position S. Consequently, the whole frame-shaped coating layer 8 is heated, whereby the sealing material layer 7 is formed.

Here, the firing method using the single firing laser light 9 is illustrated in FIG. 7. When the single firing laser light 9 is used, the irradiation is performed while it is scanned round the frame-shaped coating layer 8 once. Incidentally, two firing laser lights 9 or more may be used for the firing. For example, when the two firing laser lights 9 are used, the irradiation start position S of one of the firing laser lights 9 and the irradiation finish position F of the other firing laser light 9 need to overlap with each other.

A heating temperature of the frame-shaped coating layer 8 is preferably within a range of (T+80) to (T+550) [° C.], where T [° C.] is a softening temperature of the sealing glass. Here, the softening temperature T of the sealing glass refers to a temperature at which the sealing glass is softened to be fluidized but is not crystallized. Further, the temperature of the frame-shaped coating layer 8 when it is irradiated with the firing laser light 9 is a value measured by a radiation thermometer.

By the irradiation with the firing laser light 9 so that the temperature of the frame-shaped coating layer 8 falls within the range of (T+80) to (T+550) [° C.], the sealing glass in the sealing material melts well, whereby the sealing material is baked on the second substrate 2 and the sealing material layer 7 is formed. When the temperature of the frame-shaped coating layer 8 does not reach (T+80) [° C.], there is a risk that only a surface portion of the frame-shaped coating layer 8 melts and the whole frame-shaped coating layer 8 does not uniformly melt. When the temperature of the frame-shaped coating layer 8 is over (T+550) [° C.], the second substrate 2 and the sealing material layer 7 are likely to suffer a crack, a fracture, and the like. Further, by setting the temperature within the aforesaid temperature range, the organic binder is effectively thermally dissolved to be removed from the sealing material layer 7.

A scanning speed of the firing laser light 9 is preferably within a range of 3 mm/s to 20 mm/s. When the scanning speed is less than 3 mm/s, a firing speed lowers, which does not allow the efficient formation of the sealing material layer 7. On the other hand, when the scanning speed is over 20 mm/s, only the surface portion of the frame-shaped coating layer 8 melts to be vitrified, which lowers releasability of gas generated by thermal decomposition of the organic binder to the outside. This sometimes causes the generation of air bubbles inside the sealing material layer 7 or the deformation of its surface due to the air bubbles, and is likely to increase an amount of residual carbon. Using the sealing material layer 7 poor in a removal state of the organic binder for sealing a gap between the first and second substrates 1, 2 is liable to lower bonding strength between the first and second substrates 1, 2 and the sealing layer and to deteriorate airtightness.

Incidentally, in the scanning of the firing laser light 9, the firing laser light 9 may be moved while the position of the second substrate 2 is fixed, the second substrate 2 may be moved while the position of the firing laser light 9 is fixed, or the both may be moved relatively to each other.

The scanning speed of the firing laser light 9 is preferably adjusted according to the thickness of the frame-shaped coating layer 8. For example, in a case of the frame-shaped coating layer 8 whose thickness after the firing becomes less than 5 the scanning speed can be as high as 15 mm/s or more. Further, in a case of the frame-shaped coating layer 8 whose thickness after the firing is over 20 the scanning speed is preferably 5 mm/s or less. In a case of the frame-shaped coating layer 8 whose thickness after the firing is within a range of 5 μm to 20 μM, the scanning speed is preferably within a range of 5 mm/s to 15 mm/s.

A power density of the firing laser light 9 is preferably within a range of 100 W/cm² to 1100 W/cm². When the power density is less than 100 W/cm², it may not be possible to heat the whole frame-shaped coating layer 8 uniformly. When the power density is over 1100 W/cm², the second substrate 2 is excessively heated, which is likely to cause its crack, fracture, or the like.

Incidentally, in FIG. 6A to FIG. 6C, states where the firing laser light 9 is radiated from above the frame-shaped coating layer 8 formed on the second substrate 2 are illustrated, but the firing laser light 9 may be radiated through the second substrate 2, that is, from a side, of the second substrate 2, opposite the surface on which the frame-shaped coating layer 8 is formed.

For example, in order to shorten the firing time of the frame-shaped coating layer 8, it is effective to increase the power and the scanning speed of the firing laser light 9. For example, when the firing laser light 9 with the increased power is radiated from above the frame-shaped coating layer 8, only the surface portion of the frame-shaped coating layer 8 is liable to be vitrified. The vitrification of only the surface portion of the frame-shaped coating layer 8 causes the aforesaid various problems.

In view of these respects, when the firing laser light 9 is radiated to the frame-shaped coating layer 8 from the side, of the second substrate 2, opposite the frame-shaped coating layer 8, the gas generated by the thermal decomposition of the organic binder can escape from the surface of the frame-shaped coating layer 8 even if the vitrification starts from a portion irradiated with the firing laser light 9. It is also effective to radiate the firing laser light 9 from both upper and lower surfaces of the frame-shaped coating layer 8, that is, from the side, of the second substrate 2, where the frame-shaped coating layer 8 is formed and from the side, of the second substrate 2, opposite the frame-shaped coating layer 8.

A beam shape of the firing laser light 9 (that is, a shape of an irradiation spot) is not particularly limited. The beam shape of the firing laser light 9 is generally circular, but is not limited to the circular shape. The beam shape of the firing laser light 9 may be an elliptical shape whose minor axis is a width direction of the frame-shaped coating layer 8. According to the firing laser light 9 whose beam shape is shaped into the elliptical shape, it is possible to increase an irradiation area of the frame-shaped coating layer 8 with the firing laser light 9, and further to increase the scanning speed of the firing laser light 9. Owing to these, it is possible to shorten the firing time of the frame-shaped coating layer 8.

A beam diameter of the firing laser light 9 is preferably 0.5 mm to 3 mm. Note that the beam diameter of the firing laser light 9 is defined in a region where beam intensity becomes 13.5% of the maximum beam intensity. When the beam shape is other than the circular shape, the beam diameter is a size with which the beam intensity becomes 13.5% of the maximum beam intensity in the scanning direction.

In the firing by the firing laser light 9, the frame-shaped coating layer 8 is selectively heated. Even when the surface 2a of the second substrate 2 has the organic resin films such as color filters, the element films, and so on, the selective heating makes it possible to form the sealing material layer 7 in a good condition without giving thermal damage to the organic resin films, the element films, and so on. Further, since the selective heating is excellent in removability of the organic binder, it is possible to obtain the sealing material layer 7 excellent in sealability, reliability, and so on.

Further, as a matter of course, the firing by the firing laser light 9 is also applicable to a case where the organic resin films, the element films, and so on are not formed on the surface 2a of the second substrate 2. In such a case as well, it is possible to obtain the sealing material layer 7 excellent in sealability, reliability, and so on. Further, the firing by the firing laser light 9 consumes less energy compared with a conventional firing step by a heating furnace, and contributes to a reduction of manufacturing man-hour and manufacturing cost. Therefore, in view of energy saving, cost reduction, and so on, the firing by the firing laser light 9 is effective.

In the manufacturing method of the embodiment, a pre-process step is performed before the irradiation of the firing step is started. Performing the pre-process step makes it possible to form the sealing material layer 7 in a good condition and to form the sealing material layer 7 at low cost and with good reproducibility. In the pre-process step, the irradiation is performed at the irradiation start position S for the time within 0.2 D/V to 0.5 D/V [s], where D [mm] and V [mm/s] are the beam diameter and the scanning speed of the firing laser light 9 in the firing step respectively. The firing step and the pre-process step have a relation that the firing step is started immediately after the pre-process step is finished. This is because, if the laser irradiation is once interrupted after the pre-process step and then the firing step is performed, a portion softened by the heating in the pre-process step is cooled, and when this portion is heated again in the firing step, a new gap is liable to be formed. Therefore, it is preferable that the pre-process step and the firing step are continuously performed by using the firing laser light 9 radiated from the same radiation source.

When the sealing material layer 7 is formed by the firing laser light 9, the irradiation is performed while the firing laser light 9 is scanned so that the irradiation start position S and the irradiation finish position F at least partly overlap with each other so as to make the frame-shaped sealing material layer 7 becomes continuous as a whole. However, even if the irradiation is performed while the firing laser light 9 is scanned so that the irradiation start position S and the irradiation finish position F overlap with each other, there sometimes actually occurs a gap near the irradiation start position S or the irradiation finish position F of the sealing material layer 7.

A cause of the generation of the gap is not necessarily clear, but it is inferred as follows. For example, when the irradiation is performed while the firing laser light 9 is scanned along the frame-shaped coating layer 8 from the irradiation start position S to the irradiation finish position F as illustrated in FIG. 7, the organic binder is not sufficiently removed at the start of the irradiation and hence the organic binder remains at the irradiation start position S. Then, when the irradiation is performed while the firing laser light 9 is scanned up to the irradiation finish position F, a coating made of the sealing glass is formed so as to cover the organic binder remaining at the irradiation start position S. Thereafter, this organic binder is decomposed to be gasified, so that the coating made of the sealing glass is blown away and the gap occurs.

Performing the pre-process step before the start of the irradiation of the firing step makes it possible to reduce the residual organic binder at the irradiation start position S to reduce the size of the gap. In particular, the irradiation for the time within 0.2 D/V to 0.5 D/V [s] makes it possible to effectively prevent the organic binder from remaining at the irradiation start position S to reduce the size of the gap. When the irradiation time is less than 0.2 D/V, the removal of the organic binder is liable to be insufficient due to the insufficient irradiation time. When the irradiation time is over 0.5 D/V, productivity decreases due to an increase of the irradiation time, and a crack, a fracture, and the like are likely to be generated due to the excessive heating of the second substrate 2.

Concretely, in the pre-process step, the same firing laser light 9 as that used in the firing step is used, the scanning is temporarily stopped before the scanning in the firing step, and the irradiation start position S is irradiated with the firing laser light 9. Such a method eliminates a need for complicated power control which is required in a conventional method of reducing the scanning speed, and the like. Consequently, the generation of regions different in firing state is suppressed and the complication of an apparatus is also suppressed. Further, it is possible to shorten the firing time, as compared with the conventional method of reducing the scanning speed. Further, the gap becomes small irrespective of a widthwise position of the sealing material layer, concretely, not only at a widthwise center portion but also at both end portions, and therefore, the width of the sealing material layer 7 can be ensured, leading to good airtightness, adhesive strength, and so on.

FIG. 8 illustrates an example of the sealing material layer 7 formed through the pre-process step and the firing step. The center portion in the left and right direction in FIG. 8 is the irradiation start position S and the irradiation finish position F, and after the scanning is first performed from the irradiation start position S in the right direction, the scanning is performed to the irradiation finish position F from the left direction in FIG. 8, so that the sealing material layer 7 is formed.

Near the irradiation start position S or the irradiation finish position F of the sealing material layer 7, a gap 71 which is a discontinuous portion of the sealing material layer 7 is formed. In the case of the conventional method of adjusting the scanning speed and so on, the gap 71 is small near a widthwise center portion 72 of the sealing material layer 7, but near side surface portions 73, the gap 71 does not become small. According to the method having the pre-process step, the gap 71 becomes small near both the center portion 72 and the side surface portions 73.

In the method having the pre-process, a gap width G defined as follows can be 55 μm or less. Here, as the gap width G, a distance between a first measurement position 75 and a second measurement position 76 is measured on both side surfaces, and the larger one of these is adopted. Here, the first measurement position 75 is set as follows. Parting lines are drawn to divide the sealing material layer 7 having a projecting portion (in FIG. 8, the right sealing material layer 7) in the width direction into eight equal parts. The first measurement position 75 is a point where a tangent at an intersection point between the parting line 74 closest to the side surface of the sealing material layer 7 and the projecting portion intersects with a side surface extension. The second measurement position 76 is a side surface terminal end of the sealing material layer 7. The gap width G is preferably 50 μm or less.

The scanning speed in the firing step may be constant from the irradiation start position S up to the irradiation finish position F, or after a first firing step where irradiation is performed while the laser light is scanned at a first scanning speed, a second firing step where irradiation is performed while the laser light is scanned at a second scanning speed lower than the first scanning speed may be performed. By reducing the scanning speed when the irradiation finish position F is approached, it is possible to enhance flowability of the sealing glass near the irradiation finish position F to further reduce the size of the gap 71. Incidentally, when the first firing step and the second firing step are performed, in order to find 0.2 D/V to 0.5 D/V [s] in the pre-process step, the scanning speed of the first firing step is defined as the scanning speed V [mm/s].

FIG. 9A to FIG. 9D illustrate positional relations of the irradiation start position S and the irradiation finish position F. As illustrated in FIG. 9A, the irradiation finish position F is set in at least an already fired portion of the frame-shaped coating layer 8, that is, basically at a position that the irradiation finish position F partly overlaps with the irradiation start position S. Consequently, it is possible to make the sealing material layer 7 basically continuous. The irradiation finish position F of the firing laser light 9 is preferably set at a position so that an overlapping amount (area ratio) with the irradiation start position S is 50% or more, as illustrated in FIG. 9B. The irradiation finish position F of the firing laser light 9 is more preferably set at a position completely overlapping with the irradiation start position S as illustrated in FIG. 9C, or at a position beyond the irradiation start position S as illustrated in FIG. 9D. This can further reduce the size of the gap 71.

When the irradiation finish position F of the firing laser light 9 is set at the position beyond the irradiation start position S as illustrated in FIG. 9D, a length of a region doubly irradiated with the firing laser light 9 is not particularly limited. However, even if the overlapping region is excessively long, the size of the gap 71 does not further reduce, and the formation time of the sealing material layer 7 is accordingly elongated to lower formation efficiency. Therefore, with the beam center of the firing laser light 9 being a reference point, the overlapping region has a distance twenty times the beam diameter D of the firing laser light 9 or less, and especially preferably is five times the beam diameter D of the firing laser light 9 or less, from the center of the irradiation start position S.

As illustrated in FIG. 10A, a start position of the second firing step, with the beam center of the firing laser light 9 being a reference point, is preferably a position short of a firing end A of the already fired portion of the frame-shaped coating layer 8 by at least 1.2 times the beam diameter D of the firing laser light 9. Reducing the speed of the firing laser light 9 at a position short of the firing end A by less than 1.2 times the beam diameter D may not allow the effective reduction of the size of the gap 71. The start position of the second firing step may be any position, provided that this position is short of the firing end A of the frame-shaped coating layer 8 by 1.2 times the beam diameter D of the firing laser light 9 or more, and the speed may be reduced from a position more short of the firing end A than the position short of the firing end A by 1.2 times the beam diameter D (that is, from a position more apart from the firing end A).

However, reducing the speed from a position excessively apart from the firing end A accordingly increases the scanning time to increase the formation time of the sealing material layer 7, resulting in deterioration in formation efficiency. Therefore, as illustrated in FIG. 10B, the start position of the second firing step, with the beam center of the firing laser light 9 being the reference point, is preferably a position short of the firing end A by twenty times the beam diameter D of the firing laser light 9 or less. Thus, the start position of the second firing step is preferably a position short of the firing end A of the frame-shaped coating layer 8 by a distance within a range of 1.2 times to twenty times the beam diameter D of the firing laser light 9, and especially preferably within a range of 1.2 times to five times the beam diameter D.

The scanning speed in the first firing step is preferably within a range of 3 mm/s to 20 mm/s. On the other hand, the scanning speed in the second firing step is preferably 2 mm/s or less. Thus setting the scanning speed makes it possible to further reduce the size of the gap 71. The scanning speed in the second firing step is more preferably 0.5 mm/s or less. A lower limit value of the scanning speed in the second firing step is not particularly limited, but is preferably 0.1 mm/s or more (for example, based on the position short of the firing end A by 1.2 times the beam diameter D), in consideration of excessive heating of the second substrate 2, deterioration of formation efficiency of the sealing material layer 7, and the like.

The scanning speed of the firing laser light 9 in the second firing step is preferably 2 mm/s or less at the position, with the beam center of the firing laser light 9 being the reference point, short of the firing end A by 1.2 times the beam diameter D of the firing laser light 9 as illustrated in FIG. 11A and FIG. 11B. Since the start position of the second firing step may be the position short of the firing end A by 1.2 times the beam diameter D of the firing laser light 9 or more as described above, the scanning by the firing laser light 9 at the speed of 2 mm/s or less may be started from a position more apart from the firing end A, that is, from a position short of the firing end A by more than 1.2 times the beam diameter D of the firing laser light 9, that is, may be started from a position apart by a distance within the range of 1.2 to twenty times the beam diameter D of the firing laser light 9, as illustrated in FIG. 11C.

In FIG. 11B and FIG. 11C, the cases where the scanning speed in the second firing step is a constant speed lower than the scanning speed in the first firing step are illustrated, but the scanning speed in the second firing step is not limited to the constant speed. As illustrated in FIG. 11D, the scanning speed may be decreased at a predetermined rate from the start position of the second firing step (within the range 1.2 times to twenty times the beam diameter D) to the irradiation finish position F. In this case as well, the scanning speed at an instant when the beam center of the firing laser light 9 reaches the position short of the firing end A of the frame-shaped coating layer 8 by 1.2 times the beam diameter D of the firing laser light is preferably 2 mm/s or less. In either case, the scanning speed at the position short of the firing end A by 1.2 times the beam diameter D is preferably 2 mm/s or less, which makes it possible to reduce the size of the gap 71 with good reproducibility.

When the scanning speed in the second firing step is lower than the scanning speed in the first firing step as described above, the heating temperature of the frame-shaped coating layer 8 sometimes becomes too high if the power density of the firing laser light 9 in the second firing step is the same as that in the first firing step. In such a case, the power density of the firing laser light 9 in the second firing step is preferably made lower than the power density in the first firing step. This can prevent the excessive heating of the frame-shaped coating layer 8 and accompanying cracks, fractures, and so on of the substrate 2 and the sealing material layer 7. However, when the heating temperature of the frame-shaped coating layer 8 in the second firing step is within the aforesaid range, the firing laser light 9 may be radiated under the same condition as that in the first firing step.

Next, a laser firing apparatus as a manufacturing apparatus of the member with the sealing material layer will be described. FIG. 12 and FIG. 13 illustrate one embodiment of the laser firing apparatus.

The laser firing apparatus 21 includes a sample stage 22 where to place the second substrate 2 having the frame-shaped coating layer 8, a laser light source 23, and a laser irradiation head 24 which irradiates the frame-shaped coating layer 8 with laser light emitted from the laser light source 23, for instance.

The laser irradiation head 24 has an optical system, though not illustrated, which collects the laser light emitted from the laser light source 23 and shapes the laser light into a predetermined beam shape to irradiate the frame-shaped coating layer 8 with the laser light. The optical system will be described later. The laser light emitted from the laser light source 23 is sent to the laser irradiation head 24. The power of the laser light is controlled by a power control part 25. The power control part 25 controls the power of the laser light by, for example, controlling a current input to the laser light source 23. Further, the power control part 25 may have a power modulator which controls the power of the laser light emitted from the laser light source 23.

The firing laser light 9 radiated from the laser irradiation head 24 is radiated while scanning from the irradiation start position S up to the irradiation finish position F of the frame-shaped coating layer 8. Specifically, the laser irradiation head 24 is moved by an X stage 26 in an X direction (that is, a horizontal direction on the drawing in FIG. 13). The X stage 26 is moved in a Y direction by two Y stages 27A, 27B. The X stage 26 moves above the fixed sample stage 22 in the Y direction (that is, a vertical direction to the drawing in FIG. 24). A positional relation between the laser irradiation head 24 and the sample stage 22 is adjusted by the X stage 26 and the Y stages 27A, 27B. The X stage 26 and the Y stages 27A, 27B constitute a moving mechanism. Incidentally, the moving mechanism may be composed of, for example, the X stage 26 which moves the laser irradiation head 24 in the X direction and a Y stage which moves the sample stage 22 in the Y direction.

The X stage 26 and the Y stages 27A, 27B are controlled by a scanning control part 28. The scanning control part 28 temporarily stops the firing laser light 9 at the irradiation start position S so that the irradiation for the time within 0.2 D/V to 0.5 D/V [s] (we-process step) is performed at the irradiation start position S as described above. Thereafter, the scanning control part 28 controls the X stage 26 and the Y stages 27A, 27B (moving mechanism) so that the irradiation is performed while scanning along the frame-shaped coating layer 8 from the irradiation start position S up to the irradiation finish position F (firing step). The laser firing apparatus 21 includes a main control system which comprehensively controls the power control part 25 and the scanning control part 28. The laser firing apparatus 21 further includes a not-illustrated radiation thermometer which measures the firing temperature (heating temperature) of the frame-shaped coating layer 8. The laser firing apparatus 21 preferably includes a suction nozzle, a blast nozzle, or the like which prevents the organic binder removed from the frame-shaped coating layer 8 from adhering to the optical system and the second substrate 2.

The laser irradiation head 24 has an optical fiber 31, a condensing lens 32, an imaging lens 33, a CCD image sensor 34, a dichroic mirror 35, and a reflective mirror 36, as illustrated in FIG. 14, for instance. The optical fiber 31 transmits the laser light emitted from the laser light source 23. The condensing lens 32 collects the laser light to shape it into a desired beam shape. The imaging lens 33 and the CCD image sensor 34 are provided in order to observe a portion irradiated with the firing laser light 9. The dichroic mirror 35 and the reflective mirror 36 reflect light, other than the laser light, coming from the portion irradiated with the firing laser light 9 (transmit the laser light) to lead it to the CCD image sensor 34. Further, in the laser irradiation head 24, a radiation thermometer 37 which measures a temperature of the portion irradiated with the firing laser light 9 is installed.

A scanning example of the firing laser light 9 by the laser firing apparatus 21 will be described with reference to FIG. 7. First, the irradiation start position S of the frame-shaped coating layer 8 is irradiated with the firing laser light 9. At this time, while the irradiation position of the firing laser light 9 is fixed at the irradiation start position S, the irradiation for the time within 0.2 D/V to 0.5 D/V [s] is performed (pre-process step). Thereafter, the firing laser light 9 is scanned along the frame-shaped coating layer 8 from the irradiation start position S up to the irradiation finish position F (firing step).

The scanning speed in the firing step may be constant, or after being performed at a first scanning speed, the firing step may be performed at a second scanning speed lower than the first scanning speed. Performing the firing step at the second scanning speed lower than the first scanning speed after performing the firing step at the first scanning speed makes it possible to further reduce the size of the gap 71.

The number of the firing laser lights 9 is not limited to one but may be plural. Specifically, a plurality of laser irradiation heads 4 each capable of independent scanning are prepared, the plural firing laser lights 9 are radiated to the frame-shaped coating layer 8 from the plural laser irradiation heads 24 respectively, whereby the firing time of the frame-shaped coating layer 8 can be shortened. When the plural firing laser lights 9 are used, the irradiation start positions S of these are set so as not to overlap with each other, and the scanning is performed so that the scanning directions are the same rotation direction along the frame-shaped coating layer 8. Further, the irradiation finish positions F of the respective laser lights 9 are set so as to overlap with the irradiation start position S by the other firing laser light 9 that appears first in the moving direction thereof. Further, before the start of the scanning of each of the firing laser lights 9, the irradiation is performed for the time within 0.2 D/V to 0.5 DV [s].

Next, a method of manufacturing the electronic device will be described. As illustrated in FIG. 1B, the first substrate 1 and the second substrate 2 on whose peripheral portion the sealing material layer 7 is formed are stacked via the sealing material layer 7, with the surfaces 1a, 2a facing each other. Thereafter, as illustrated in FIG. 1C, the sealing material layer 7 is irradiated with sealing laser light 10 through the second substrate 2 from above the second substrate 2 of a glass assembly formed by the stacking.

The sealing laser light 10 may be radiated to the sealing material layer 7 through the first substrate 1 from under the first substrate 1 opposite the second substrate 2 of the glass assembly formed by the stacking. Alternatively, the sealing laser light 10 may be radiated from both sides, that is, from above the second substrate 2 of the glass assembly formed by the stacking and from under the first substrate 1 opposite the second substrate 2 of the glass assembly formed by the stacking.

The irradiation is performed while the sealing laser light 10 is scanned along the sealing material layer 7. The sealing material layer 7 melts from its portion irradiated with the laser light 10, and when the irradiation with the sealing laser light 10 is finished, is rapidly cooled to be solidified to fixedly adhere to the first substrate 1. Then, the sealing laser light 10 is radiated all along the periphery of the sealing material layer 7, whereby a sealing layer 11 sealing a gap between the first substrate and the second substrate 2 is formed as illustrated in FIG. 1D. In this manner, the electronic device 12 in which the electronic element part 4 is hermetically sealed between the first substrate 1 and the second substrate 2 is fabricated.

According to the manufacturing steps of the electronic device 12 of the embodiment, even when the organic resin films, the element films, and so on are formed on the surface 2a of the second substrate 2, it is possible to form the sealing material layer 7 and the sealing layer 11 in a good condition without giving any thermal damage to these. Therefore, it is possible to fabricate the electronic device 12 excellent in hermetic sealability and reliability without deteriorating a function of the electronic device 12 and its reliability.

### EXAMPLES

Next, concrete examples of the present invention and evaluation results thereof will be described. Note that the following description does not limit the present invention, and changes conforming to the spirit of the present invention can be made.

### Example 1

As a bismuth-based glass frit, one that had a composition containing 83 mass % Bi₂O₃, 5 mass % B₂O₃, 11 mass % ZnO, and 1 mass % Al₂O₃, had a 1 μm average particle size, and had a 410° C. softening temperature was prepared. As a low-expansion filler, a cordierite powder that had a 0.9 μm average particle size and a 12.4 m²/g specific surface area was prepared. As a laser absorbing material, one that had a composition of Fe₂O₃—Al₂O₃—MnO—CuO, a 1.9 μm average particle size, and an 8.3 m²/g specific surface area was prepared.

The specific surface areas of the cordierite powder and the laser absorbing material were measured by using a BET specific surface area analyzer (manufactured by Mountech Co., Ltd., device name: Macsorb I-1M model-1201). Measurement conditions were as follows.

adsorbate: nitrogen

carrier gas: helium

measurement method: flow method (BET one point method)

deaeration temperature: 200° C.

deaeration time: twenty minutes

deaeration pressure: N₂ gas flow, atmospheric pressure

sample mass: 1 g

85.0 mass % of the aforesaid bismuth-based glass frit, 6.6 mass % of the cordierite powder, and 8.4 mass % of the laser absorbing material were mixed to fabricate a sealing material. 90 mass % of the sealing material was mixed with a 10 mass % vehicle to prepare a sealing material paste. In the vehicle, ethyl cellulose (5 mass %) as an organic binder was dissolved in a solvent (95 mass %) made of 2,2,4-trimethyl-1,3-pentanediol monoisobutyrate.

Next, a second substrate (dimension: 90×90×0.7 mmt) made of alkali free glass (coefficient of thermal expansion: 38×10⁻⁷/K) was prepared. On its sealing region, the sealing material paste was applied in a frame shape by a dispensing method, followed by drying under a condition of 120° C.×ten minutes, whereby a frame-shaped coating layer was formed. The sealing material paste was applied so that a film thickness after the drying became 8 μm.

Next, the second substrate on which the frame-shaped coating layer was formed was disposed on a sample stage of a laser irradiation apparatus. Thereafter, irradiation was first performed for 0.06 seconds while a position of firing laser light was fixed at an irradiation start position of the frame-shaped coating layer (pre-process step). Thereafter, the irradiation was performed up to an irradiation finish position while the firing laser light was scanned round and along the frame-shaped coating layer (start region to finish region) once at a 5 mm/s scanning speed (firing step). A heating temperature of the frame-shaped coating layer at this time was 660° C. In this manner, the whole frame-shaped coating layer was fired by the firing laser light, whereby a member with a sealing material layer having a sealing material layer with a 4.5 μm film thickness and a 0.5 mm width was manufactured.

Here, the irradiation finish position was set at a position so that a beam center of the firing laser light was beyond a firing end of the frame-shaped coating layer by 2 mm in a scanning direction. The start region was a region from the irradiation start position up to a position to which the firing laser light moved by 1.8 mm. The finish region was a region short of the firing end and a region whose beam center was distant from the firing end by 1.8 mm. Further, a region between the start region and the finish region was set as a scanning region. Incidentally, when the firing step is composed of a first firing step and a second firing step, the start region and the scanning region are regions undergoing the first firing step, and the finish region is a region undergoing the second firing step.

The firing laser light had an 808 nm wavelength, a 385 W/cm² power density, a circular beam shape with a 1.5 mm diameter. The beam shape was measured by using a laser beam profiler (manufactured by Ophir Optonics Solutions Ltd, device name: BS-USB-SP620), and a diameter with which beam intensity became 13.5% of the maximum beam intensity was set as the beam diameter. The laser power was measured by using a power meter (manufactured by Coherent, Inc., device name: FieldMaxll-TO) and a head (manufactured by Coherent, Inc., device name: PM100-19C).

When a state of the sealing material layer was observed by SEM, it was confirmed that the whole sealing material layer was vitrified well. No occurrence of air bubbles and surface deformation ascribable to the organic binder was recognized in the sealing material layer. Further, a gap width G (FIG. 8) measured at the irradiation finish position was 45 μm. Further, a film thickness of a projecting portion (FIG. 8) of the sealing material layer measured at a widthwise center portion of the sealing material layer was 5.4 μm at the maximum. Further, when an amount of residual carbon of the sealing material layer was measured, it was confirmed that the residual carbon amount was equal to that when the same frame-shaped coating layer was fired (480° C.×ten minutes) by an electric furnace.

Next, the aforesaid member with the sealing material layer (the second substrate having the sealing material layer) and a first substrate (substrate having the same composition and made of alkali free glass having the same shape as those of the second substrate) having an element region were stacked. Next, sealing laser light was radiated through the second substrate from an irradiation start point, which was a side facing a side having the gap, while scanning along the sealing material layer, and the sealing material layer was melted and rapidly cooled to be solidified, whereby the first substrate and the second substrate are sealingly bonded to fabricate a hermetic vessel. It was confirmed that the obtained hermetic vessel was excellent in appearance, bonding strength, and so on and was also excellent in airtightness.

Similarly, 100 pieces of members with a sealing material layer were fabricated, the number of pieces in which the substrate was fractured was checked, and its occurrence ratio was calculated. Further, each of 100 pieces of the members with the sealing material layer was sealingly bonded with the first substrate to fabricate hermetic vessels, the number of the hermetic vessels suffering a fracture in a sealed portion was confirmed, and its occurrence ratio was calculated. Their results are also presented in Table 1.

### Examples 2 to 6

Members with a sealing material layer were manufactured in the same manner as that of the example 1 except that a beam diameter of laser light, the irradiation time at an irradiation start position (time of a pre-process step), a scanning speed (start region to finish region), power density, heating temperature of a frame-shaped coating layer, and so on were changed to the conditions illustrated in Table 1.

When a state of each of the sealing material layers was observed by SEM, it was confirmed that the whole sealing material layer was vitrified well. Further, in the same manner as that of the example 1, various properties were evaluated. As a result, it was confirmed that bonding strength and airtightness of hermetic vessels were good and the occurrence of fracture (the members with the sealing material layer, the hermetic vessels) was suppressed.

### Example 7

A sealing material layer was formed in the same manner as that of the example 1 except that a scanning speed of laser light in a frame-shaped coating layer (finish region) was changed to 1 mm/s and its power density was changed to 294 W/cm². A heating temperature of the frame-shaped coating layer at this time was 660° C. The whole frame-shaped coating layer was thus fired by the laser light, whereby a member with a sealing material layer having a 4.5 μm film thickness was manufactured.

When a state of the sealing material layer was observed by SEM, it was confirmed that the whole sealing material layer was vitrified well. Further, various properties were evaluated in the same manner as that of the example 1. As a result, it was confirmed that bonding strength and airtightness of a hermetic vessel were good and the occurrence of fracture (the member with the sealing material layer, the hermetic vessel) was suppressed.

### Comparative Example 1

A member with a sealing material layer was manufactured in the same manner as that of the example 1 except that a pre-process step was not performed. Thereafter, various properties were evaluated in the same manner as that of the example 1. As a result, it was confirmed that a gap width G was large, bonding strength and airtightness of a hermetic vessel were deteriorated, and many factures (hermetic vessel) occurred, as presented in Table 1.

### Comparative Example 2

A member with a sealing material layer was manufactured in the same manner as that of the example 1 except that the time of a pre-process step was changed to the condition presented in Table 1. Thereafter, various properties were evaluated in the same manner as that of the example 1. As a result, it was confirmed that a gap width G was smaller than those in the examples 1 to 7. However, bonding strength and airtightness of a hermetic vessel were deteriorated, and many factures (the member with the sealing material layer, the hermetic vessel) occurred.

### Comparative Example 3

A member with a sealing material layer was manufactured in the same manner as that of the example 1 except that a pre-process step was not performed and a scanning speed in a frame-shaped coating layer (finish region) was changed to 1 mm/s. Thereafter, various properties were evaluated in the same manner as that of the example 1. As a result, it was confirmed that one having good bonding strength and airtightness could be obtained, but since a gap width G was larger than those in the examples 1 to 7, many fractures occurred (the member with the sealing material layer, a hermetic vessel), and a yield as a whole was low.

### Comparative Example 4

A member with a sealing material layer was manufactured in the same manner as that of the example 1 except that a pre-process step was not performed and a scanning speed in a frame-shaped coating layer (start region and finish region) was changed to 1 mm/s. Thereafter, various properties were evaluated in the same manner as that of the example 1. As a result, it was confirmed that one having good bonding strength and airtightness could be obtained, but since a gap width G was larger than those in the examples 1 to 7, many fractures occurred (the member with the sealing material layer, a hermetic vessel), and a yield as a whole was low.

TABLE 1

| | | | Example | | | | | | | Comparative Example | | | |
|---|---|---|---|---|---|---|---|---|---|---|---|---|---|
| | | | 1 | 2 | 3 | 4 | 5 | 6 | 7 | 1 | 2 | 3 | 4 |
| beam diameter D [mm] | | | φ1.5 | φ1.5 | φ1.5 | φ1.5 | φ2.5 | φ1.0 | φ1.5 | φ1.5 | φ1.5 | φ1.5 | φ1.5 |
| (pre- | irradiation | irradiation | 0.06 | 0.1 | 0.15 | 0.07 | 0.25 | 0.1 | 0.06 | 0 | 0.3 | 0 | 0 |
| process | start | time [s] | | | | | | | | | | | |
| step) | position | | | | | | | | | | | | |
| (first | start | scanning speed | 5 | 5 | 5 | 10 | 5 | 5 | 5 | 5 | 5 | 5 | 1 |
| firing | region | [mm/s] | | | | | | | | | | | |
| step) | | irradiation intensity | 385 | 385 | 385 | 475 | 278 | 468 | 385 | 385 | 385 | 385 | 294 |
| | | [W/cm²] | | | | | | | | | | | |
| | scanning | scanning speed | 5 | 5 | 5 | 10 | 5 | 5 | 5 | 5 | 5 | 5 | 5 |
| | region | [mm/s] | | | | | | | | | | | |
| | | irradiation intensity | 385 | 385 | 385 | 475 | 278 | 468 | 385 | 385 | 385 | 385 | 385 |
| | | [W/cm²] | | | | | | | | | | | |
| (second | finish | scanning speed | 5 | 5 | 5 | 10 | 5 | 5 | 1 | 5 | 5 | 1 | 1 |
| firing | region | [mm/s] | | | | | | | | | | | |
| step) | | irradiation intensity | 385 | 385 | 385 | 475 | 278 | 468 | 294 | 385 | 385 | 294 | 294 |
| | | [W/cm²] | | | | | | | | | | | |

| | | | | | | | | | | | |
|---|---|---|---|---|---|---|---|---|---|---|---|
| coefficient of D/V | 0.2 | 0.33 | 0.5 | 0.47 | 0.5 | 0.5 | 0.2 | 0 | 1.0 | 0 | 0 |
| gap width G [μm] | 45 | 40 | 35 | 30 | 40 | 30 | 30 | 150 | 20 | 80 | 60 |
| maximum film thickness | 5.4 | 5.3 | 5.1 | 5 | 5.3 | 5 | 5 | 8.5 | 5 | 5.8 | 5.6 |
| of projecting portion [μm] | | | | | | | | | | | |
| adhesive strength | good | good | good | good | good | good | good | poor | poor | good | good |
| airtightness | good | good | good | good | good | good | good | poor | poor | good | good |
| fracture occurrence ratio [%] | 0 | 0 | 0 | 0 | 0 | 0 | 0 | 0 | 30 | 40 | 40 |
| (member with sealing material layer) | | | | | | | | | | | |
| fracture occurrence ratio [%] | 0 | 0 | 0 | 0 | 0 | 0 | 0 | 20 | 50 | 50 | 50 |
| (hermetic vessel) | | | | | | | | | | | |

What is claimed is:

1. A method of manufacturing a member with a sealing material layer, the method comprising:
preparing a substrate having a frame-shaped sealing region;
applying a sealing material paste prepared by mixing a sealing material containing sealing glass and a laser absorbing material with a vehicle containing an organic binder, on the sealing region of the substrate to form a frame-shaped coating layer;
firing the sealing material to form a sealing material layer while removing the organic binder in the frame-shaped coating layer, by performing irradiation while scanning firing laser light along the frame-shaped coating layer to heat the whole frame-shaped coating layer; and
irradiating at an irradiation start position for 0.2 D/V to 0.5 D/V [s] before the step of firing, D [mm] and V [mm/s] being a beam diameter and a scanning speed of the firing laser light in the firing respectively.

2. The method of manufacturing the member with the sealing material layer according to claim 1,
wherein the step of irradiating and the step of the firing are performed continuously.

3. The method of manufacturing the member with the sealing material layer according to claim 1,
wherein the scanning speed of the firing laser light in the step of firing is 3 mm/s to 20 mm/s.

4. The method of manufacturing the member with the sealing material layer according to claim 1,
wherein the beam diameter of the firing laser light in the step of firing is 0.5 mm to 3 mm.

5. The method of manufacturing the member with the sealing material layer according to claim 1,
wherein the step of firing includes: performing a first firing by performing irradiation while scanning firing laser light while the firing laser light is scanned at a first scanning speed;
and performing a second firing by performing irradiation while scanning firing laser light, after the first firing, while the firing laser light is scanned at a second scanning speed lower than the first scanning speed.

6. The method of manufacturing the member with the sealing material layer according to claim 5,
wherein the first scanning speed is 3 mm/s to 20 mm/s and the second scanning speed is 2 mm/s or less.

7. The method of manufacturing the member with the sealing material layer according to claim 5,
wherein the second firing is started when a beam center of the firing laser light reaches a position short of an irradiation finish position of the firing laser light by 1.2 times to twenty times the beam diameter of the firing laser light.

8. The method of manufacturing the member with the sealing material layer according to claim 1,
wherein the sealing material layer has a 20 μm thickness or less.

9. The method of manufacturing the member with the sealing material layer according to claim 1,
wherein the sealing material contains 0.1 vol % to 40 vol % of the laser absorbing material and 0 vol % to 50 vol % of a low-expansion filler, a total amount of the laser absorbing material and the low-expansion filler being in a range of 0.1 vol % to 50 vol %.

10. The method of manufacturing the member with the sealing material layer according to claim 1,
wherein the substrate is a glass substrate.

11. A member with a sealing material layer, comprising:
a substrate having a frame-shaped sealing region; and
a sealing material layer provided on the sealing region of the substrate, and
the member with the sealing material layer being manufactured by the method of manufacturing the member with the sealing material layer according to claim 1.

12. A method of manufacturing an electronic device, comprising:
preparing a first substrate having a first surface on which a frame-shaped first sealing region is provided and a second substrate having a second surface on which a second sealing region corresponding to the first sealing region is provided;
applying a sealing material paste prepared by mixing a sealing material containing sealing glass and a laser absorbing material with a vehicle containing an organic binder, on the second sealing region of the second substrate to form a frame-shaped coating layer;
firing the sealing material to form a sealing material layer while removing the organic binder in the frame-shaped coating layer, by performing irradiation while scanning firing laser light along the frame-shaped coating layer to heat the whole frame-shaped coating layer;
stacking the first substrate and the second substrate via the sealing material layer, with the first surface and the second surface facing each other;
irradiating the sealing material layer with sealing laser light via the first substrate or the second substrate to melt the sealing material layer to form a sealing layer which seals an electronic element part provided between the first substrate and the second substrate; and
irradiating at an irradiation start position for 0.2 D/V to 0.5 D/V [s] before the step of firing, D [mm] and V [mm/s] being a beam diameter and a scanning speed of the firing laser light in the firing respectively.

13. An electronic device, comprising:
a first substrate having a first surface on which a frame-shaped first sealing region is provided;
a second substrate having a second surface on which a second sealing region corresponding to the first sealing region is provided and is disposed, with the first surface and the second surface facing each other; and
a sealing layer disposed in a frame shape so as to seal an electronic element part between the first substrate and the second substrate, and
the electronic device being manufactured by the method of manufacturing the electronic device according to claim 12.

14. A manufacturing apparatus of a member with a sealing material layer, the apparatus comprising:
a sample stage where to place a substrate having a frame-shaped coating layer of a sealing material paste prepared by mixing a sealing material containing sealing glass and a laser absorbing material with a vehicle containing an organic binder;
a laser light source which emits firing laser light;
a laser irradiation head having an optical system which irradiates the frame-shaped coating layer of the substrate with the laser light emitted from the laser light source;
a power control part which controls power of the firing laser light with which the frame-shaped coating layer is irradiated by the laser irradiation head;
a moving mechanism which relatively moves positions of the sample stage and the laser irradiation head; and
a scanning control part which controls the moving mechanism so that irradiation is performed while the firing laser light is scanned along the frame-shaped coating layer and irradiation is performed at an irradiation start position of the firing laser light for 0.2 D/V to 0.5 D/V [s], where D [mm] is a beam diameter of the firing laser light and V [mm/s] is a scanning speed of the firing laser light.
